(19) United States
(12) Patent Application Publication
(10) Pub. No.: US 2004/0018796 A1
(43) Pub. Date: Jan. 29, 2004

(54) Method of manufacturing display device

(75) Inventor: Takashi Hamada, Atsugi (JP)

Correspondence Address: NIXON PEABODY, LLP, 401 9TH STREET, NW, SUITE 900, WASINGTON, DC, 20004-2128, US

(73) Assignee: Semiconductor Energy Laboratory Co., Ltd., Atsugi-shi (JP)

(21) Appl. No.: 10/617,770

(22) Filed: Jul. 14, 2003

(30) Foreign Application Priority Data
Jul. 26, 2002 (JP) 2002-218563

(51) Int. Cl. H01J 9/00; H01J 9/24

(52) U.S. Cl. 445/24

(57) ABSTRACT

In the formation of a thin film on a substrate on which thin film transistors are formed with an electron beam evaporation method, there is provided a technique of forming a desired thin film without incurring abnormality in characteristics of the thin film transistor. The technique is characterized in that, in the formation of a thin film on an electrode, which is electrically connected with a thin film transistor, with an electron beam evaporation method, control of an acceleration voltage of electrons is performed such that, when an evaporation material for forming the thin film is irradiated with an electron beam, radial rays are not substantially radiated from the evaporation material. That the radial rays are not substantially radiated indicates that the control of an acceleration voltage of electrons is performed such that the thin film transistor is not deteriorated due to radial rays radiated from the evaporation material.

### BACKGROUND OF THE INVENTION

1. Field of the Invention

The present invention relates to a method of manufacturing a display device having an active element (typically a transistor) formed in each pixel, and more particularly to a method of manufacturing an active matrix display device in which a light emitting element formed of an electroluminescence material and the active element are used in combination to form a pixel.

2. Description of the Related Art

In recent years, developments of liquid crystal display devices and electroluminescence display devices having transistors, specifically, thin film transistors or MOS transistors integrated on substrates, have been progressing. Those display devices are each characterized in that the transistors are formed on a glass substrate using a thin film formation technique and the obtained transistors are arranged in pixels arranged in matrix to function as a display device for displaying an image.

The above-described pixel structure is called an active matrix system because active elements like transistors are used in the structure. FIG. 2 shows a typical structure of an electroluminescence display device of the active matrix system. In FIG. 2, reference numeral 201 denotes a substrate. A thin film transistor 202 is provided thereon, and is connected with a first electrode 203 that functions as an anode of a light emitting element. Further, provided on the first electrode 203 is an insulating film 204 having an opening portion at the position corresponding to the electrode. A light emitter 205 and a second electrode 206 that functions as a cathode of the light emitting element are provided so as to cover the above members. In the electroluminescence display device, the light emitter 205 is made to emit light through current injection, thereby performing image display.

The first electrode 203 and the second electrode 206 are distinguished from each other by respectively being expressed as the anode and the cathode. A material with high hole-injecting property to the light emitter 205 is applied as an electrode material for forming the anode while a material having high electron-injecting property is applied as an electrode material for forming the cathode. For example, it is considered that a material with a work function of 3 eV or less is preferably used as the electrode material for forming the cathode. An AlLi alloy, AgMg alloy, and the like are typically used.

At this time, a general process can be adopted up through the formation of the first electrode 203 and the insulating film 204. However, in the case of using an organic compound for the light emitter 205, an evaporation method, application method, ink-jet method, or printing method is used as a film deposition method. Further, the evaporation method is used for the formation of the second electrode 206 since the heat resistance of the light emitter 205 is low at 100° C. or less.

The present inventors have found that abnormality in a threshold voltage and in sub-threshold characteristics is recognized in the electroluminescence display device with the structure of FIG. 2 which is manufactured in the process of research and development. As a result of the diagnosis of the cause of the abnormality, it has been found that a significant shift of a threshold voltage (Vₜₕ) is seen between the values before and after the formation of a metal film, which is to serve as a cathode, with an electron beam evaporation method. The results in FIGS. 3A and 3B show drain voltage-gate voltage characteristics (hereinafter referred to as I_{D}-V_{G} characteristics) of a thin film transistor before and after the formation of a metal film that becomes a cathode. As apparent from FIGS. 3A and 3B, it has become clear that the threshold voltage after the formation of the cathode moves to the minus side by approximately 4 V compared with the threshold voltage before the formation thereof. Further, it has been confirmed that a sub-threshold coefficient (S value), which shows steepness of switching characteristics, is increased (deteriorated). It is considered the reason for this is that some damage is caused to the thin film transistor in the formation of the cathode, as a result of which the threshold voltage and the S value are heavily changed.

### SUMMARY OF THE INVENTION

The present invention has been made in view of the above, and therefore has an object to provide a technique of forming a desired thin film on a substrate, on which thin film transistors are formed, without incurring characteristic abnormality thereof.

What is considered as the cause of the characteristic abnormality of the thin film transistor is the influence that arises from damage due to radial rays, that is, deterioration in characteristics due to generation of electric charge or level in a gate insulating film. A malfunction of the transistor due to the radial-ray damage is a well-known phenomenon, and is generally classified into three: the occurrence of positive electric charge in an oxide film; the occurrence of an interface level of an Si—SiO₂ interface; and the occurrence of neutral-electron trap in an oxide film, which arise from irradiation of radial rays (gamma rays, neutron, X-rays, etc.). The malfunction of the transistor due to the radial-ray damage is described in detail in, for example, ‘edit. Kenji Taniguchi, et al., “silicon thermal oxidation film and interface thereof”, Realize KK., pp. 167-182 (Jul. 31, 1991)’.

Further, in an electron beam evaporation method, it is considered that radial rays (typically, characteristic X-rays) are generated from metal melted due to irradiation with an electron beam. The present inventors have arrived at a conclusion that the occurrence of positive electric charge and the formation of an interface level are caused in a gate insulating film or the like in a thin film transistor due to the radial rays generated in electron beam evaporation, which leads to the shift of a threshold voltage to the minus side, namely, the generation of characteristic abnormality.

According to a first structure of the present invention, which has been made on the basis of the findings, there is provided a method of manufacturing a display device characterized in that in the formation of a thin film on an electrode, which is electrically connected with a thin film transistor with an electron beam evaporation method, control of an acceleration voltage of electrons is performed such that, when an evaporation material for forming the thin film is irradiated with an electron beam, radial rays are not substantially radiated from the evaporation material. The term “radial rays are not substantially radiated” means that the acceleration voltage of the electrons is controlled such that the thin film transistor is not deteriorated due to the radial rays radiated from the evaporation material.

Also, the method of manufacturing a display device is characterized in that in the formation of a light emitter containing an organic compound on a first electrode, which is electrically connected with a thin film transistor on a substrate and whose surface is exposed, and the formation of a second electrode on the light emitter with an electron beam evaporation method, control of an acceleration voltage of electrons is performed such that, when an evaporation material for forming the second electrode is irradiated with an electron beam, radial rays are not substantially radiated from the evaporation material. The term “radial rays are not substantially radiated” means that the acceleration voltage of the electrons is controlled such that the thin film transistor is not deteriorated due to the radial rays radiated from the evaporation material.

In electron beam evaporation, the acceleration voltage of electrons is controlled such that the radial rays are not substantially radiated from the evaporation material. Thus, the radial-ray damage of the thin film transistor is suppressed, whereby the characteristic deterioration can be reduced.

According to a second structure of the present invention which is made on the basis of the findings, there is provided a method of manufacturing a display device in which, in the formation of a thin film transistor on a substrate and the formation of a thin film on an electrode, which is electrically connected with the thin film transistor and whose surface is exposed, with an electron beam evaporation method, control is performed such that, when an evaporation material for forming the thin film is irradiated with an electron beam, a time, during which the thin film transistor is exposed to radial rays radiated from the evaporation material, is shortened with a thickness of the thin film of 0.1 μm or less to thereby avoid deterioration of the thin film transistor.

In the formation of the thin film on the electrode connected with the thin film transistor with the electron beam evaporation method, the thickness is set to 0.1 μm or less. That is, the time during which the thin film transistor is exposed to the radial rays is shortened. As a result, the radial-ray damage of the thin film transistor is suppressed, whereby the characteristic deterioration can be reduced.

### BRIEF DESCRIPTION OF THE DRAWINGS

In the accompanying drawings:

FIGS. 1A and 1B are a top view and a cross-sectional view of a pixel structure of a display device, respectively;

FIG. 2 is a cross-sectional view of a pixel structure of a display device;

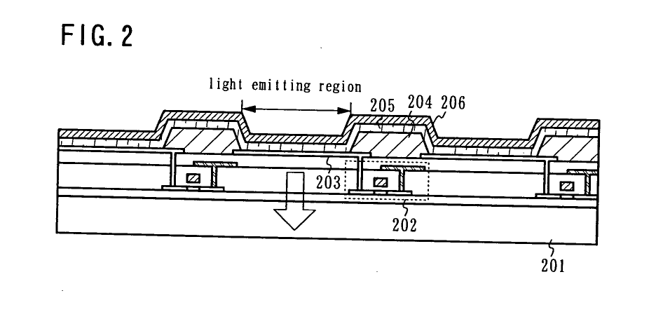

FIGS. 3A and 3B are graphs each of which shows I_{D}-V_{G} characteristics of a thin film transistor in terms of change in characteristics before and after evaporation of an electron beam;

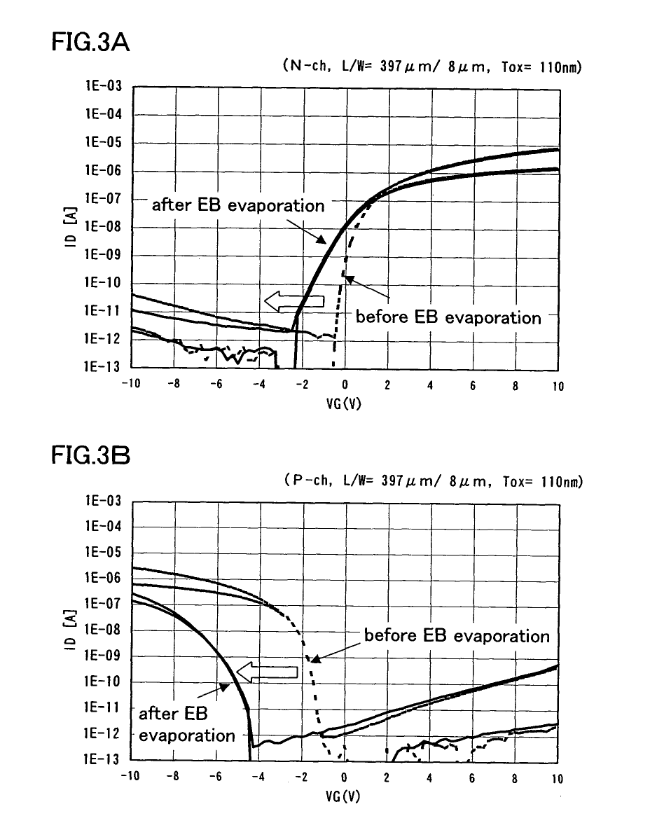

FIG. 4 is a graph showing evaporation-time dependence of an S value of a thin film transistor through irradiation of radial rays;

FIG. 5 is an explanatory view of an experimental system used for obtaining the data in FIG. 4 in Embodiment 2; and

FIGS. 6A to 6H are diagrams of examples of electronic devices.

### DETAILED DESCRIPTION OF THE PREFERRED EMBODIMENTS

Hereinafter, embodiments of the present invention will be described in detail with reference to the accompanying drawings. Incidentally, the present invention can be implemented in various embodiments, and it is easily understood by those skilled in the art that the forms and details of the invention can be variously changed without departing from the gist and the scope thereof. Therefore, the present invention is not construed within the limit of the contents described in the embodiments of the present invention.

### Embodiment 1

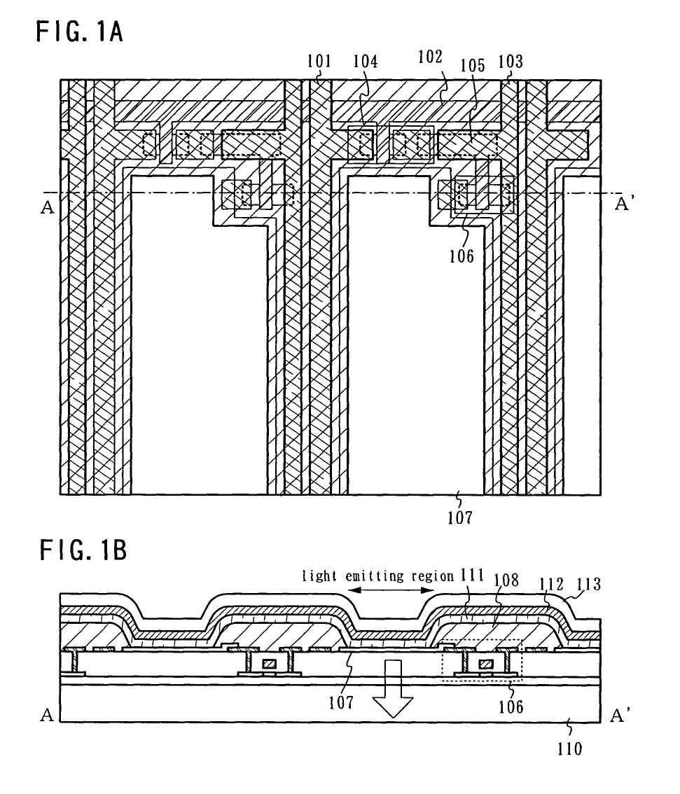

The embodiment of the present invention will be described with reference to FIGS. 1A and 1B. In a pixel structure shown in FIG. 1A, reference numeral 101 denotes a data signal line; 102 denotes a gate signal line; 103 denotes a power source line; 104 denotes a thin film transistor for switching (referred to as switching TFT; hereinafter, the same applied); 105 denotes a capacitor for holding electric charge; 106 denotes a thin film transistor for driving for supplying a current to a light emitting element (referred to as driving TFT; hereinafter, the same applied); and 107 denotes a first electrode electrically connected with a drain of the driving TFT. The first electrode 107 functions as an anode of the light emitting element. Here, the light emitting element indicates an element in which a light emitter is provided between a pair of electrodes (anode and cathode). For example, an electroluminescence element is provided as the light emitting element in this embodiment.

FIG. 1B is a view corresponding to a cross section taken along A-A′ at this time. In FIG. 1B, reference numeral 110 denotes a substrate, which may be comprised of a glass substrate, a quartz substrate, a plastic substrate, or other translucent substrates. The driving TFT 106 is formed on the substrate 110 by a known semiconductor process. Further, a partition layer 108, which is patterned in a lattice shape, is provided so as to cover an end portion of the first electrode 107, which is formed to be connected with the driving TFT 106, and at least the driving TFT and the switching TFT.

Polycrystalline silicon or amorphous silicon is applied to a semiconductor layer that forms a channel portion of the switching TFT 104 or the driving TFT 106, and there is no particular limitation placed on a gate structure and the like. Known techniques of a single drain, low-concentration drain, and the like can be applied. The structure of the thin film transistor shown in the figure is a top gate structure (specifically, a planar structure). Besides, a bottom gate structure (specifically, a reverse stagger structure) can be adopted as another form. In this case, the point of difference is only that the arrangement of a semiconductor layer and a gate electrode etc. is reversed. As a matter of course, a transistor with a MOS structure, which is formed of a single crystal silicon wafer with the use of a silicon well, may be applied besides the thin film transistor.

A light emitter 111, a second electrode 112 that functions as a cathode, and a passivation film 113 are provided on the first electrode 107 and the partition layer 108. The part, where the first electrode 107, the light emitter 111, and the second electrode 112 are superimposed on one another, substantially corresponds to the light emitting element.

A known structure can be used for the structure of the light emitter 111. The light emitter, which is arranged between the first electrode 107 and the second electrode 112, includes a light emitting layer, hole injecting layer, electron injecting layer, hole transporting layer, electron transporting layer, and the like, and can take a form in which the above layers are laminated or a form in which parts or all of the materials for forming the above layers are mixed with one another. Specifically, the light emitter includes the light emitting layer, hole injecting layer, electron injecting layer, hole transporting layer, electron transporting layer, and the like. An EL element basically has a structure in which a lamination layer is constituted of an anode/light emitting layer/cathode in order, and besides, may have a structure in which a lamination layer is constituted of, for example, an anode/hole injecting layer/light emitting layer/cathode or anode/hole injecting layer/light emitting layer/electron transporting layer/cathode in order.

The light emitter 111 is typically formed of an organic compound, but is formed of a charge injection transporting substance, which contains an organic compound or inorganic compound, and a light emitting material. The light emitter 111 includes a layer of one or plural kinds selected from the group consisting of a low molecular weight organic compound, intermediate molecular weight organic compound, and high molecular weight organic compound, which are relative to molecularity, and the layer may be combined with the inorganic compound with electron injection transporting property or hole injection transporting property. Note that middle molecules indicate an organic compound that does not have subliming property and that has a molecularity of 20 or less, or length of chained molecules of 10 μm or less.

As to a light emitting material that serves as a main body of the light emitter 111, metal complexes such as a tris-8-quinolinolato aluminum complex and bis(benzo quinolilato)beryllium complex, phenyl anthracene derivative, tetraaryldiamine derivative, distyryl benzene derivative, and the like may be applied as the low molecular weight organic compound. With the above substances serving as host substances, a coumarin derivative, DCM, quinacridone, rubrene, and the like are applied. Further, other known materials can be applied. As the polymer organic compound, there are polyparaphenylene vinylene-based, polyparaphenylene-based, polythiophene-based, and polyfluorene-based compounds. For example, poly(p-phenylene vinylene): PPV, poly(2,5-dialkoxy-1,4-phenylenevinylene): RO-PPV, poly[2-(2′-ethylhexoxy)-5-methoxy-1,4-phenylene vinylene]: MEH-PPV, poly[2-(dialkoxyphenyl)-1,4-phenylene vinylene]: ROPh-PPV, poly[p-phenylene]: PPP, poly(2,5-dialkoxy-1,4-phenylene): RO-PPP, poly((2,5-dihexoxy-1,4-phenylene), polythiophene: PT, poly(3-alkylthiophene): PAT, poly(3-hexylthiophene): PHT, poly(3-cyclohexylthiophene): PCHT, poly(3-cyclohexyl-4-methylthiophene): PCHMT, poly(3,4-dicyclohexylthiophene): PDCHT, poly[3-(4-octylphenyl)-thiophenel]: POPT, poly[3-(4-octylphenyl)-2,2-bithiophene]: PTOPT, polyfluorene: PF, poly(9,9-dialkylfluorene): PDAF, poly(9,9-dioctylfluorene): PDOF and the like can be given.

Inorganic compound materials may be applied to the charge injection transporting layer, include diamond-like carbon (DLC), Si, Ge, and oxide or nitride of the above substances, and may be appropriately doped with P, B, N, or the like. Further, the inorganic compound materials may include an oxide, nitride, and fluoride of alkali metal or alkali earth metal and a compound or alloy of the above metal and at least Zn, Sn, V, Ru, Sm, or In.

The materials given above are examples. The respective functional layers such as the hole injection transporting layer, hole transporting layer, electron injection transporting layer, electron transporting layer, light emitting layer, electron blocking layer, and hole blocking layer are appropriately laminated, thereby being capable of forming the light emitter 111. Further, a mixture layer or mixture junction may be formed by combining the respective layers. Electroluminescence includes light emission in returning to a base state from a singlet excitation state (fluorescence) and light emission in returning to a base state from a triplet excitation state (phosphorescence). The electroluminescence element according to the present invention may employ either or both of the two types of light emission.

As to the passivation film 113, a silicon nitride film, aluminum nitride film, diamond-like carbon film, and other insulating films having high blocking property against moisture and oxygen may be used.

A multi-component alloy or compound, which is constituted of a metal component and a component containing either or both of alkali metal and alkali earth metal, is used for the second electrode 112. Al, Au, Fe, V, and Pd are given as examples of the metal components. Specific examples of alkali metal or alkali earth metal include Li (lithium), Na (sodium), K (potassium), Rb (rubidium), Cs (cesium), Mg (magnesium), Ca (calcium), Sr (strontium), and Ba (barium). In addition, Yb (ytterbium), Lu (lutetium), Nd (neodymium), Tm (thulium), and the like may be applied. It is defined that the composition of the second electrode corresponds to an alloy or compound in which 0.01 to 10% by weight of alkali metal or alkali earth metal with a work function of 3 eV or less is contained in the metal component. For the purpose of making the second electrode function as the cathode, the thickness of the second electrode may be appropriately set. However, the second electrode may be formed by an electron beam evaporation method in the thickness range of about 0.01 to 1 μm.

Here, in the formation of the second electrode 112 with the electron beam evaporation method, an acceleration voltage is controlled such that, when an evaporation material containing the metal component is irradiated with electrons, radial rays are not substantially radiated from the material. It is sufficient that the acceleration voltage at which the radial rays are not radiated from the evaporation material is generally set to 2 kV or less although depending on the kind of the material.

Of course, since a film deposition speed is lowered along with the lowering of the acceleration voltage, the problem of the decrease of productivity arises. Under the purpose of making the second electrode 112 function as the cathode, it is sufficient that the second electrode 112 has a thickness of approximately 0.01 to 1 μm. Thus, a low-resistance metal material such as Al may be laminated on the second electrode by a resistance heating evaporation method or sputtering method for the reduction in resistance.

As described above, according to the manufacturing method in this embodiment, film deposition can be performed without being influenced by the radial rays in the formation of the metal film with the use of the electron beam evaporation method. Therefore, there can be suppressed the occurrence of failures such as abnormality in a threshold voltage and S-value abnormality of the transistor which arise from the irradiation of radial rays.

### Embodiment 2

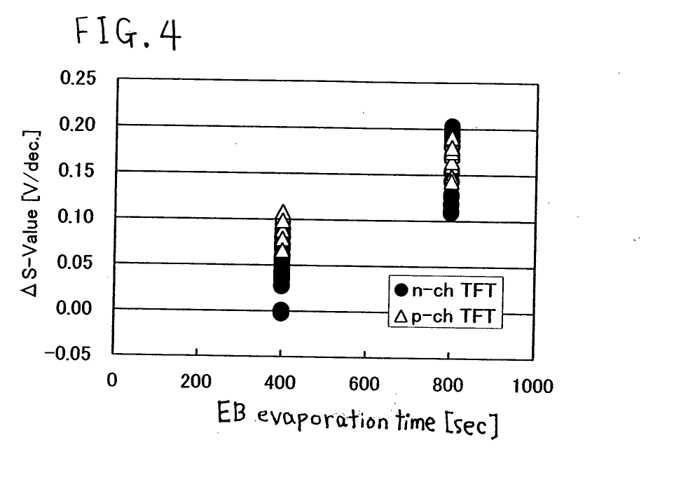

It is observed that, in regard to the change in characteristics of a thin film transistor due to radial rays, there is a tendency that the change amount increases in proportion to a time during which the transistor is exposed to the radial rays. FIG. 4 is, as an example, a graph showing an electron beam evaporation time and a change amount of an S value (sub-threshold coefficient) of a thin film transistor. The data is obtained by examining the relationship between the irradiation time of radial rays and the change in characteristics of the thin film transistor in a pseudo manner. The data shows characteristics of an S-value transistor at a threshold voltage or less (sub-threshold characteristics), and is defined as a value of a gate voltage required for the change of a drain current for one digit. The increase of the S value, that is, the reduction of the gradient of the sub-threshold characteristics indicates the deterioration of switching characteristics of the transistor.

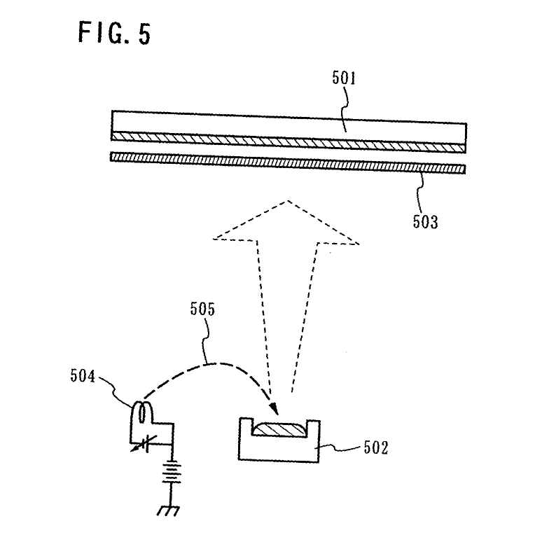

As shown in FIG. 5, an experimental system has a structure in which: an aluminum foil 503 is intervened between an evaporation source 502 and a substrate 501, on which thin film transistors are formed, in an electron beam evaporation device; and an evaporation material does not directly fly and adhere to the substrate. In this state, an electron beam 505 is emitted toward the evaporation source 502 from an electron gun 504 as in general evaporation.

FIG. 4 shows the results of irradiation of the evaporation material with electrons at a fixed acceleration voltage. There is shown a tendency that S values of both a p-channel thin film transistor and an n-channel thin film transistor increase along with the increase of the irradiation time (evaporation time). That is, the lowering of the switching characteristics is shown.

In the structures shown in FIGS. 1A and 1B, it is sufficient that: the second electrode 112 in the light emitting element formed by the electron beam evaporation method functions as a cathode or anode; and the sheet resistance is several hundreds of Ω/□ or less. In the case where Al or the like is used as a metal material, it is sufficient that the thickness is set to 0.1 μm or less, preferably 0.01 to 0.05 μm. That is, in the second structure of the present invention, the time for electron beam evaporation is shortened through the reduction in thickness of the second electrode, whereby deterioration of the thin film transistor can be suppressed. In other words, control can be performed such that the time during which the thin film transistor is exposed to the radial rays radiated from the evaporation material is shortened to thereby avoid the deterioration of the thin film transistor.

Of course, for the purpose of attaining the reduction in resistance, an auxiliary electrode may be formed on the second electrode, which is reduced in thickness to 0.1 μm or less, by a film deposition method, which cause no influence of radial rays, such as a resistance heating evaporation method or a sputtering method.

As described above, according to the manufacturing method in this embodiment, in the formation of the metal film with the electron beam evaporation method, the film deposition can be performed without being influenced by the radial rays. As a result, there can be suppressed the occurrence of failures such as abnormality in a threshold voltage and S-value abnormality of the transistor which arise from the irradiation of radial rays.

### Embodiment 3

The display device shown in Embodiments 1 and 2 each exemplify an electroluminescence display device. However, the present invention can be applied to all of the manufacturing processes that form a transistor on a substrate and then form a predetermined thin film by an electronic beam evaporation method. For instance, the present invention can be applied to the processes for manufacturing a liquid crystal display device, a field emission display device and other display devices that use the electric beam evaporation method.

### Embodiment 4

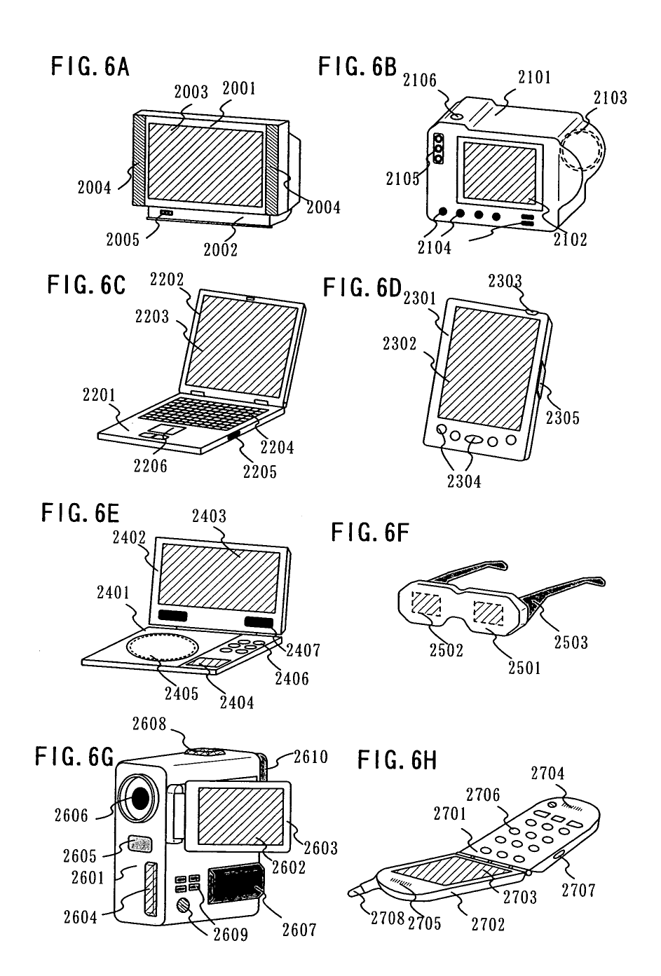

Examples of electronic devices using the display devices of the present invention in display portions include video cameras, digital cameras, goggle type displays (head mounted displays), navigation systems, audio systems (car audio, audio components, etc.), notebook type personal computers, game machines, portable information terminals (mobile computers, mobile telephones, mobile type game machines, electronic books, etc.), and image reproduction devices equipped with a recording medium (specifically, devices equipped with a display capable of reproducing the recording medium such as a digital versatile disc (DVD) and displaying the image thereof). Specific examples of the electronic devices are shown in FIGS. 6A to 6H.

FIG. 6A shows a television, which is composed of a frame 2001, a support 2002, a display portion 2003, a speaker portion 2004, a video input terminal 2005, and the like. The present invention may be applied to the display portion 2003. Note that all televisions for displaying information, such as personal computer monitors, display devices for receiving TV broadcasting, and display devices for advertising are also included.

FIG. 6B shows a digital camera, which is composed of a main body 2101, a display portion 2102, an image-receiving portion 2103, operation keys 2104, an external connection port 2105, a shutter 2106, and the like. The present invention may be applied to the display portion 2102.

FIG. 6C shows a notebook type personal computer, which is composed of a main body 2201, a frame 2202, a display portion 2203, a keyboard 2204, external connection ports 2205, a pointing mouse 2206, and the like. The present invention may be applied to the display portion 2203.

FIG. 6D shows a mobile computer, which is composed of a main body 2301, a display portion 2302, switches 2303, operation keys 2304, an infrared port 2305, and the like. The present invention may be applied to the display portion 2302.

FIG. 6E shows a portable image reproduction device provided with a recording medium (specifically, a DVD reproduction device), which is composed of a main body 2401, a frame 2402, a display portion A 2403, a display portion B 2404, a recording medium (such as a DVD) read-in portion 2405, operation keys 2406, a speaker portion 2407, and the like. The present invention can be applied to both of the display portion A 2403 and the display portion B 2404 while the display portion A 2403 mainly displays image information, and the display portion B 2404 mainly displays character information. Note that image reproduction device provided with a recording medium includes game machines for domestic use and the like.

FIG. 6F shows a goggle type display (head mounted display), which is composed of a main body 2501, a display portion 2502, an arm portion 2503, and the like. The present invention may be applied to the display portion 2502.

FIG. 6G shows a video camera, which is composed of a main body 2601, a display portion 2602, a frame 2603, external connection ports 2604, a remote control receiving portion 2605, an image receiving portion 2606, a battery 2607, an audio input portion 2608, operation keys 2609, and the like. The present invention may be applied to the display portion 2602.

FIG. 6H shows a mobile telephone, which is composed of a main body 2701, a frame 2702, a display portion 2703, an audio input portion 2704, an audio output portion 2705, operation keys 2706, external connection ports 2707, an antenna 2708, and the like. The present invention may be applied to the display portion 2703. Note that, by displaying white characters on a black background, it is possible to suppress the power consumption of the mobile telephone.

The display device that is obtained by applying the present invention thereto can be used in the display portions of various electronic devices. Note that the display device having the structure of any one of Embodiments 1 to 3 can be used for the electronic device of this embodiment.

According to the present invention, particularly in the formation of the metal film with the electron beam evaporation method, the defects of the transistor which is formed on the substrate to be processed is irradiated with the radial rays such as the gamma rays, neutron, or X-rays are eliminated, and the malfunction along with the occurrence of positive electric charge in an oxide film, the occurrence of an interface level of an Si—SiO₂ interface, and the occurrence of neutral-electron trap in an oxide film which arise from the irradiation of radial rays can be avoided. As a result, a display device with high reliability can be obtained by preventing the abnormality in the threshold voltage and the S-value abnormality from occurring.

What is claimed is:

1. A method of manufacturing a display device, wherein, in the formation of a thin film on an electrode, which is electrically connected with a thin film transistor on a substrate and whose surface is exposed, with an electron beam evaporation method, control of an acceleration voltage of electrons is performed such that, when an evaporation material for forming the thin film is irradiated with an electron beam, radial rays are not substantially radiated from the evaporation material.

2. A method of manufacturing a display device, wherein, in the formation of a thin film on an electrode, which is electrically connected with a thin film transistor on a substrate and whose surface is exposed, with an electron beam evaporation method, control of an acceleration voltage of electrons is performed such that, when an evaporation material for forming the thin film is irradiated with an electron beam, the thin film transistor is not deteriorated with radial rays radiated from the evaporation material.

3. A method of manufacturing a display device, wherein, in the formation of a light emitter containing an organic compound on a first electrode, which is electrically connected with a thin film transistor on a substrate and whose surface is exposed, and the formation of a second electrode on the light emitter with an electron beam evaporation method, control of an acceleration voltage of electrons is performed such that, when an evaporation material for forming the second electrode is irradiated with an electron beam, radial rays are not substantially radiated from the evaporation material.

4. A method of manufacturing a display device, wherein, in the formation of a light emitter containing an organic compound on a first electrode, which is electrically connected with a thin film transistor on a substrate and whose surface is exposed, and the formation of a second electrode on the light emitter with an electron beam evaporation method, control of an acceleration voltage of electrons is performed such that, when an evaporation material for forming the second electrode is irradiated with an electron beam, the thin film transistor is not deteriorated with radial rays radiated from the evaporation material.

5. A method of manufacturing a display device, wherein, in the formation of a thin film on an electrode, which is electrically connected with a thin film transistor on a substrate and whose surface is exposed, with an electron beam evaporation method, control is performed such that, when an evaporation material for forming the thin film is irradiated with an electron beam, a time during which, the thin film transistor is exposed to radial rays radiated from the evaporation material, is shortened with a thickness of the thin film of 0.1 μm or less to thereby avoid deterioration of the thin film transistor.

6. A method of manufacturing a display device, wherein, in the formation of a light emitter containing an organic compound on a first electrode, which is electrically connected with a thin film transistor on a substrate and whose surface is exposed, and the formation of a second electrode on the light emitter with an electron beam evaporation method, control is performed such that, when an evaporation material for forming the thin film is irradiated with an electron beam, a time during which, the thin film transistor is exposed to radial rays radiated from the evaporation material, is shortened with a thickness of the second electrode of 0.1 μm or less to thereby avoid deterioration of the thin film transistor.

7. A method of manufacturing a display device according to claim 1, wherein a multi-component alloy or compound, which is constituted of a metal component and a component containing either or both of alkali metal and alkali earth metal, is used as the evaporation material.

8. A method of manufacturing a display device according to claim 2, wherein a multi-component alloy or compound, which is constituted of a metal component and a component containing either or both of alkali metal and alkali earth metal, is used as the evaporation material.

9. A method of manufacturing a display device according to claim 3, wherein a multi-component alloy or compound, which is constituted of a metal component and a component containing either or both of alkali metal and alkali earth metal, is used as the evaporation material.

10. A method of manufacturing a display device according to claim 4, wherein a multi-component alloy or compound, which is constituted of a metal component and a component containing either or both of alkali metal and alkali earth metal, is used as the evaporation material.

11. A method of manufacturing a display device according to claim 5, wherein a multi-component alloy or compound, which is constituted of a metal component and a component containing either or both of alkali metal and alkali earth metal, is used as the evaporation material.

12. A method of manufacturing a display device according to claim 6, wherein a multi-component alloy or compound, which is constituted of a metal component and a component containing either or both of alkali metal and alkali earth metal, is used as the evaporation material.
